(19) United States
(12) Patent Application Publication
(10) Pub. No.: US 2013/0105125 A1
(43) Pub. Date: May 2, 2013

(54) INDOOR UNIT OF AIR-CONDITIONING APPARATUS

(71) Applicants: Masayuki Oishi, Tokyo (JP); Shoji Yamada, Tokyo (JP); Tomoya Fukui, Tokyo (JP)

(72) Inventors: Masayuki Oishi, Tokyo (JP); Shoji Yamada, Tokyo (JP); Tomoya Fukui, Tokyo (JP)

(73) Assignee: Mitsubishi Electric Corporation, Tokyo (JP)

(21) Appl. No.: 13/592,385

(22) Filed: Aug. 23, 2012

(30) Foreign Application Priority Data
Oct. 26, 2011 (JP) 2011-235071

(51) Int. Cl. H01L 23/467

(52) U.S. Cl. 165/121

(57) ABSTRACT

[Object] An object is to obtain an indoor unit of an air-conditioning apparatus, the indoor unit including a propeller fan in the vicinity of an air inlet, the indoor unit being capable of ensuring the strength of a casing and suppressing degradation of performance by reducing an increase in draft resistance of sucked-in air.

[Solution] In an indoor unit 1 of an air-conditioning apparatus, at least one propeller fan 10 having a fan guard 50 is disposed downstream of an air inlet 130 formed at the top of the indoor unit 1. The air inlet 130 is provided with bars 140. Each of the bars 140 is located, in a vertical cross-section perpendicular to the longitudinal direction of the bar 140, within a virtual cylinder 13 obtained by projecting a boss 11 of the propeller fan 10 in the direction of the rotation axis of the propeller fan 10.

### TECHNICAL FIELD

The present invention relates to an indoor unit of an air-conditioning apparatus.

### BACKGROUND ART

Various types of air-sending devices have been proposed, such as a once-through fan used in an indoor unit of an air-conditioning apparatus. Among the air-sending devices proposed is a propeller fan which is provided with a fan guard that prevents human fingers from touching blades (see, e.g., Patent Literature 1).

### CITATION LIST

### Patent Literature

[Patent Literature 1] Japanese Unexamined Patent Application Publication No. 2001-132695 (Abstract, FIG. 3)

### SUMMARY OF INVENTION

### Technical Problem

An indoor unit of an air-conditioning apparatus needs to include bars in an air inlet to ensure the strength of a casing (i.e., indoor unit). Therefore, when, as an air-sending device for the indoor unit, a propeller fan (such as that described above) is placed in the vicinity of the air inlet of the indoor unit, bars which may cause draft resistance are provided on the upwind side of the propeller fan in addition to a fan guard. The bars in the air inlet may be configured to also serve as a fan guard. In other words, it may be possible that the bars in the air inlet be arranged at intervals that do not allow the entry of human fingers. However, since the casing of the indoor unit is typically formed by resin molding, it is difficult in practice to form closely-spaced thin bars, such as those of a fan guard, in the air inlet. As a result, when, as an air-sending device for the indoor unit, a propeller fan (such as that described above) is placed in the vicinity of the air inlet of the indoor unit, the bars formed in the air inlet increase the draft resistance of sucked-in air and degrade the performance of the indoor unit of the air-conditioning apparatus.

The present invention has been made to solve the problems described above. An object of the present invention is to obtain an indoor unit of an air-conditioning apparatus, the indoor unit including a propeller fan in the vicinity of an air inlet, the indoor unit being capable of ensuring the strength of a casing and suppressing degradation of performance by restraining an increase in draft resistance of sucked-in air.

### Solution to Problem

An indoor unit of an air-conditioning apparatus according to the present invention includes a casing having an air inlet at the top thereof and an air outlet on a lower side of the front thereof; at least one propeller fan disposed in the casing and located downstream of the air inlet, the propeller fan being provided with a fan guard; and a heat exchanger disposed in the casing and located downstream of the propeller fan, the heat exchanger being configured to exchange heat between air sucked into the casing by the propeller fan and refrigerant. The air inlet is provided with a plurality of bars. The bars in the air inlet are located, in a vertical cross-section perpendicular to the longitudinal direction of the bars, within a virtual cylinder obtained by projecting a boss of the propeller fan in the direction of the rotation axis of the propeller fan.

### Advantageous Effects of Invention

In the present invention, the bars formed in the air inlet of the casing are located, in a vertical cross-section perpendicular to the longitudinal direction of the bars, within a virtual cylinder obtained by projecting the boss of the propeller fan in the direction of the rotation axis of the propeller fan. Therefore, it is possible to reduce the area of the bars that overlap with blades of the propeller fan when the bars in the air inlet are projected onto the propeller fan along the rotation axis of the propeller fan. It is thus possible to suppress an increase in draft resistance caused by the bars. Therefore, the present invention can suppress degradation in performance of the indoor unit of the air-conditioning apparatus while ensuring the strength of the casing.

### BRIEF DESCRIPTION OF DRAWINGS

FIG. 1 is a perspective view illustrating an indoor unit of an air-conditioning apparatus according to Embodiment 1 of the present invention.

FIG. 2 is a plan view illustrating the vicinity of an air inlet of the indoor unit of the air-conditioning apparatus according to Embodiment 1 of the present invention.

FIG. 3 is a cross-sectional view (vertical cross-sectional view) taken along line Z-Z of FIG. 1.

FIG. 4 is an exploded perspective view illustrating the indoor unit of the air-conditioning apparatus according to Embodiment 1 of the present invention.

FIG. 5 is a plan view illustrating the vicinity of the air inlet in an example of the indoor unit of the air-conditioning apparatus according to Embodiment 2 of the present invention.

FIG. 6 is a perspective view illustrating a filter of the indoor unit of the air-conditioning apparatus illustrated in FIG. 5.

FIG. 7 is a plan view illustrating the vicinity of the air inlet in another example of the indoor unit of the air-conditioning apparatus according to Embodiment 2 of the present invention.

FIG. 8 is a perspective view illustrating a filter of the indoor unit of the air-conditioning apparatus illustrated in FIG. 7.

FIG. 9 is a plan view illustrating still another example of the indoor unit of the air-conditioning apparatus according to Embodiment 2 of the present invention.

FIG. 10 is a plan view illustrating still another example of the indoor unit of the air-conditioning apparatus according to Embodiment 2 of the present invention.

### DESCRIPTION OF EMBODIMENTS

### Embodiment 1

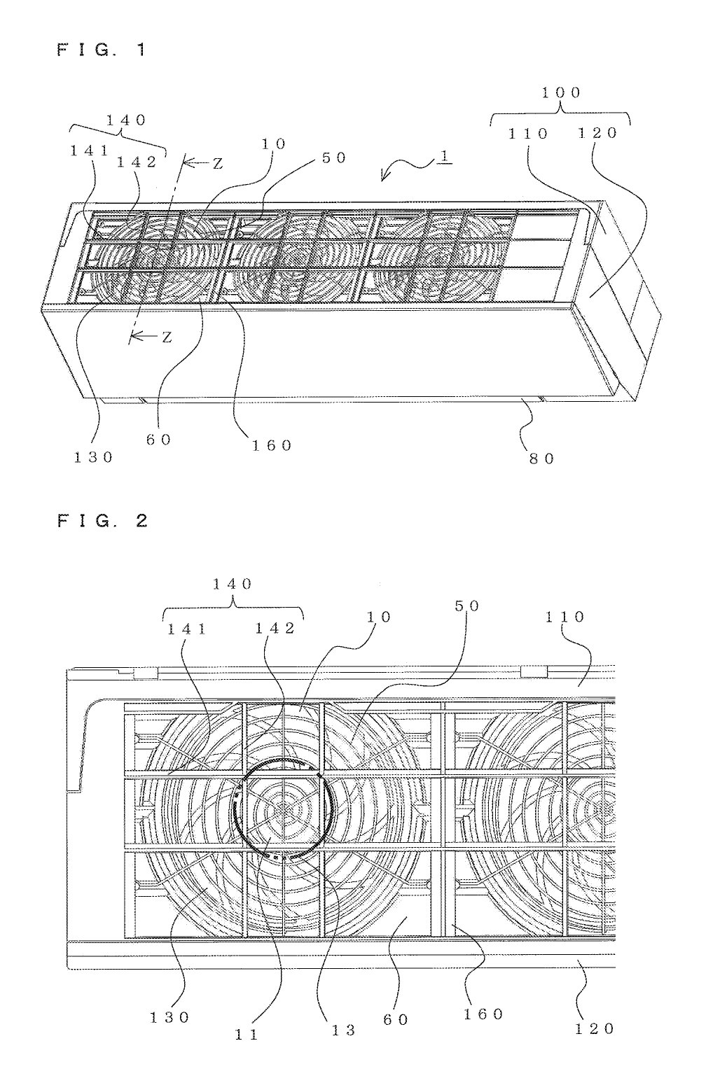

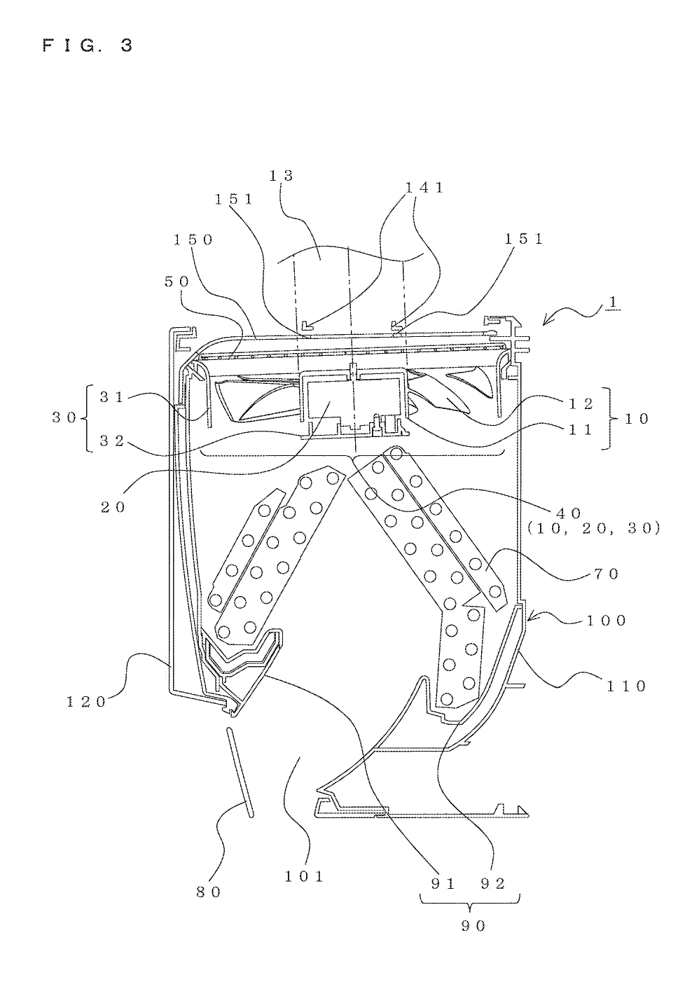

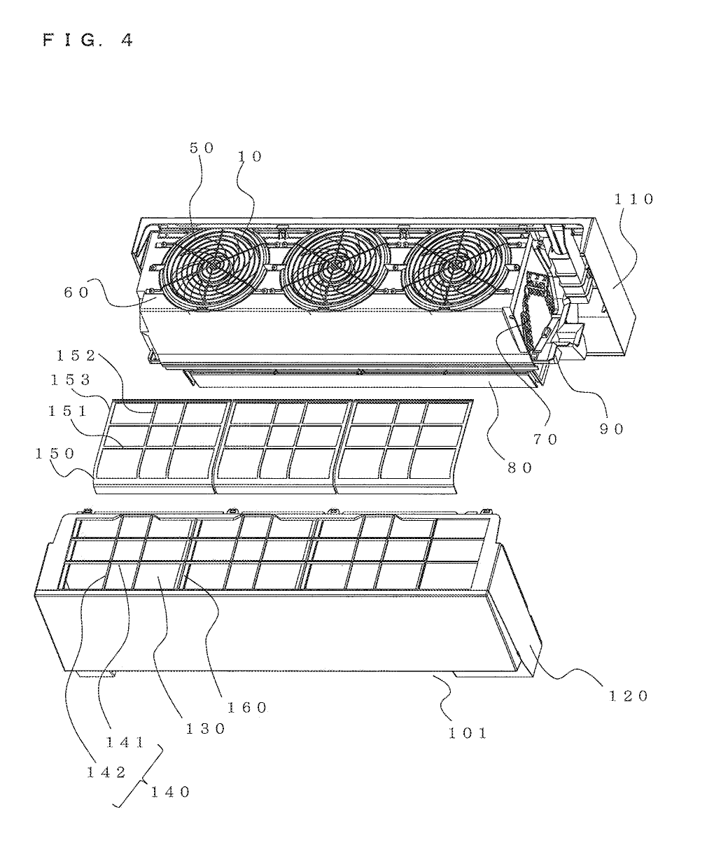

FIG. 1 is a perspective view illustrating an indoor unit of an air-conditioning apparatus according to Embodiment 1 of the present invention. FIG. 2 is a plan view illustrating the vicinity of an air inlet of the indoor unit of the air-conditioning apparatus. FIG. 3 is a cross-sectional view (vertical cross-sectional view) taken along line Z-Z of FIG. 1. FIG. 4 is an exploded perspective view illustrating the indoor unit of the air-conditioning apparatus. Hereinafter, an indoor unit 1 of an air-conditioning apparatus according to Embodiment 1 will be described with reference to FIG. 1 to FIG. 4.

The indoor unit 1 includes a casing 100 having a plurality of air inlets 130 at the top thereof and an air outlet 101 on a lower side of the front thereof. The casing 100 includes three propeller fans 10 each having a fan guard 50 on the upstream side thereof, and also includes a heat exchanger 70 that exchanges heat between air and refrigerant sucked into the casing 100. Specifically, the propeller fans 10 are located downstream of the air inlets 130 and arranged side by side in the horizontal direction of the casing 100. The heat exchanger 70 is disposed downstream of the propeller fans 10 and upstream of the air outlet 101. For removing dust from indoor air flowing into the casing 100, the indoor unit 1 according to Embodiment 1 includes filters 150 between the air inlets 130 and the propeller fans 10.

The casing 100 according to Embodiment 1 includes a housing 110 and a panel 120. The housing 110 forms the rear face, the rear parts of side faces, and the lower face of the casing 100. The propeller fans 10 and the heat exchanger 70 are attached to the housing 110. The panel 120 forms the front face, the front parts of side faces, and the upper face of the casing 100. The air inlets 130 of the casing 100 are formed in the upper face of the panel 120. The air outlet 101 of the casing 100 is formed between the front edge of the lower face of the housing 110 and the lower edge of the front face of the panel 120. In Embodiment 1, the propeller fans 10 are attached to the housing 110 through a propeller-fan mount unit 30.

As described above, the three propeller fans 10 are arranged side by side in the casing 100. Accordingly, the panel 120 is provided with three air inlets 130 at positions corresponding to the respective propeller fans 10. Each of the air inlets 130 is, for example, substantially rectangular in shape and is internally provided with a plurality of bars 140. In Embodiment 1, the bars 140 include two horizontal bars 141 and two vertical bars 142. That is, the two horizontal bars 141 and the two vertical bars 142 are provided for each of the propeller fans 10. For attaching and removing the filters 150, there are guides 160 between adjacent air inlets 130.

The horizontal bars 141 and the vertical bars 142 in the air inlets 130 are provided to ensure the strength of the panel 120 (i.e., indoor unit 1). However, the horizontal bars 141 and the vertical bars 142 cause draft resistance of air sucked from the air inlets 130 into the casing 100. Therefore, in Embodiment 1, the horizontal bars 141 and the vertical bars 142 are arranged in the following manner to suppress an increase in draft resistance caused by the horizontal bars 141 and the vertical bars 142. As illustrated in FIG. 3, a range obtained by projecting a boss 11 of the propeller fan 10 in the direction of the rotation axis of the propeller fan 10 is defined as a virtual cylinder 13. In this case, as illustrated in FIG. 2 and FIG. 3, the horizontal bars 141 are located within the virtual cylinder 13 in a vertical cross-section perpendicular to the longitudinal direction of the horizontal bars 141. Similarly, as illustrated in FIG. 2, the vertical bars 142 are located within the virtual cylinder 13 in a vertical cross-section perpendicular to the longitudinal direction of the vertical bars 142.

As described above, for removing dust from indoor air flowing into the casing 100, the indoor unit 1 according to Embodiment 1 includes the filters 150 between the air inlets 130 and the propeller fans 10. The filters 150 are also provided with horizontal bars 151 and vertical bars 152 in an outer frame 153 to ensure their strength. The horizontal bars 151 and the vertical bars 152 also cause draft resistance of air sucked into the casing 100. Therefore, in Embodiment 1, the horizontal bars 151 and the vertical bars 152 are arranged such that when the filters 150 are mounted on the casing 100, the horizontal bars 151 and the vertical bars 152 face the horizontal bars 141 and the vertical bars 142, respectively, in the air inlets 130.

Each propeller fan 10 that includes the boss 11 and blades 12 protruding on the outer surface of the boss 11 is disposed downstream of the corresponding air inlet 130, as described above. A fan motor 20 disposed to be covered by the boss 11 is connected to the propeller fan 10. The propeller fan 10 is rotated about the center of the boss 11 by rotary drive of the fan motor 20. The propeller fan 10 and the fan motor 20 are attached to the propeller-fan mount unit 30. Specifically, the propeller-fan mount unit 30 includes a bell mouth 31 configured to surround the propeller fan 10 and a fan-motor securing part 32 configured to secure the fan motor 20. The propeller fan 10 is placed in the bell mouth 31 by attaching the fan motor 20 to the fan-motor securing part 32.

In Embodiment 1, the propeller fan 10 is attached to the housing 110 of the casing 100, for example, in the following steps. First, the propeller fan 10, the fan motor 20, and the propeller-fan mount unit 30 are assembled into a propeller fan assembly 40 in advance. Next, the propeller fan assembly 40 including the three components is attached to a securing component 60, while the fan guard 50 for the propeller fan 10 is attached to the securing component 60 to cover the upwind side of the propeller fan assembly 40. Then, the securing component 60 to which the propeller fan assembly 40 and the fan guard 50 have been attached is attached to the housing 110 of the casing 100. Thus, since the propeller fan assembly 40 and the fan guard 50 are attached to the securing component 60 in advance, the number of worker-hours for assembly of the indoor unit 1 can be reduced.

The heat exchanger 70 disposed downstream of the propeller fan 10 is, for example, substantially A-shaped in vertical cross-section. A drain pan assembly 90 that allows drain condensed by the heat exchanger 70 to flow to the outside of the indoor unit 1 is disposed below the heat exchanger 70. The drain pan assembly 90 includes a front drain pan 91 disposed below the lower end of the front of the heat exchanger 70 and a rear drain pan 92 disposed below the lower end of the rear of the heat exchanger 70. The front drain pan 91 and the rear drain pan 92 are integrally formed to define a nozzle therebetween that communicates with the air outlet 101. The heat exchanger 70 and the drain pan assembly 90 are attached, together with the securing component 60, to the housing 110 of the casing 100. In the indoor unit 1 according to Embodiment 1, the air outlet 101 is provided with a wind-direction flap 80 for regulating the direction of air blown out of the air outlet 101. The wind-direction flap 80 is also attached to the housing 110 of the casing 100.

### (Description of Operation)

The indoor unit 1 of the air-conditioning apparatus configured as described above operates as follows.

When the propeller fan 10 is rotated by rotary drive of the fan motor 20, indoor air is sucked from the air inlet 130 into the casing 100. There is concern here that the horizontal bars 141 and the vertical bars 142 in the air inlet 130 may cause draft resistance of the indoor air and may result in degradation of the performance of the indoor unit 1, such as an increase in noise level and a deterioration of input to the fan motor 20. However, in Embodiment 1, the horizontal bars 141 and the vertical bars 142 in the air inlet 130 are located within the virtual cylinder 13 in a cross-section perpendicular to the longitudinal direction of these bars. Therefore, it is possible to reduce the area of the horizontal bars 141 and the vertical bars 142 that overlap with the blades 12 of the propeller fan 10 when the horizontal bars 141 and the vertical bars 142 are projected onto the propeller fan 10 along the rotation axis of the propeller fan 10. In the wake flow of the horizontal bars 141 and the vertical bars 142, there is a steep velocity defect region (where the flow velocity is slow). In the velocity defect region, where the velocity of airflow changes significantly, strong air eddies and turbulence are produced by shearing stress caused by a difference in velocity of airflow. However, when the horizontal bars 141 and the vertical bars 142 are arranged as in Embodiment 1, it is possible to reduce turbulent wake flow of the horizontal bars 141 and the vertical bars 142 into the blades 12 which are turning at high speed. Therefore, it is possible to suppress degradation in performance of the indoor unit 1, such as an increase in noise level and a deterioration of input to the fan motor 20.

As described above, in the indoor unit 1 of the air-conditioning apparatus according to Embodiment 1, the horizontal bars 141 and the vertical bars 142 in the air inlet 130 are located within the virtual cylinder 13 in a cross-section perpendicular to the longitudinal direction of these bars. Therefore, it is possible to reduce turbulent wake flow of the horizontal bars 141 and the vertical bars 142 into the blades 12 which are turning at high speed, and suppress degradation in performance of the indoor unit 1, such as an increase in noise level and a deterioration of input to the fan motor 20.

At the same time, the horizontal bars 151 and the vertical bars 152 of the filter 150 are arranged at positions corresponding to the horizontal bars 141 and the vertical bars 142 formed in the air inlet 130. Therefore, even if the indoor unit 1 includes the filter 150, it is possible to suppress degradation in performance of the indoor unit 1, such as an increase in noise level and a deterioration of input to the fan motor 20.

Although the indoor unit 1 includes three propeller fans 10 in Embodiment 1, there may be any number of propeller fans 10 in the indoor unit 1. The heat exchanger 70 is not limited to a substantially A-shape in vertical cross-section and may be of any shape.

### Embodiment 2

In Embodiment 1, the bars 140 in each air inlet 130 include two horizontal bars 141 and two vertical bars 142, which are arranged in a grid. The number and arrangement of the horizontal bars 141 and the vertical bars 142 included in the bars 140 are not limited to this, and may be determined appropriately depending on, for example, the required strength of the casing 100 (i.e., indoor unit 1). Hereinafter, examples of the configuration of the bars 140 will be described. Note that, unless otherwise specified, Embodiment 2 is the same as Embodiment 1, and identical functions and components will be described using the same reference numerals.

For example, if the strength of the casing 100 (i.e., indoor unit 1) can be ensured without connecting each of the horizontal bars 141 and the vertical bars 142, at both ends, to the edge of the air inlet 130, the bars 140 may be configured as illustrated in FIG. 5.

FIG. 5 is a plan view illustrating the vicinity of the air inlet in an example of the indoor unit of the air-conditioning apparatus according to Embodiment 2 of the present invention.

In the indoor unit 1 illustrated in FIG. 5, as in the indoor unit 1 according to Embodiment 1, the horizontal bars 141 and the vertical bars 142 in the air inlet 130 are located within the virtual cylinder 13 in a cross-section perpendicular to the longitudinal direction of these bars. However, in the indoor unit 1 illustrated in FIG. 5, unlike in the indoor unit 1 according to Embodiment 1, the horizontal bars 141 and the vertical bars 142 are connected at one ends to respective intersections of the horizontal bars 141 and the vertical bars 142.

With this arrangement of the horizontal bars 141 and the vertical bars 142, as compared to Embodiment 1, it is possible to reduce the area of the horizontal bars 141 and the vertical bars 142 that overlap with the blades 12 of the propeller fan 10 when the horizontal bars 141 and the vertical bars 142 are projected onto the propeller fan 10 along the rotation axis of the propeller fan 10. Therefore, as compared to Embodiment 1, it is possible to reduce turbulent wake flow of the horizontal bars 141 and the vertical bars 142 into the blades 12 which are turning at high speed, and suppress degradation in performance of the indoor unit 1, such as an increase in noise level and a deterioration of input to the fan motor 20.

In the indoor unit 1 illustrated in FIG. 5, all the horizontal bars 141 and the vertical bars 142 are connected at one ends to the respective intersections of the horizontal bars 141 and the vertical bars 142. However, the configuration of the horizontal bars 141 and the vertical bars 142 is not limited to this. For example, at least one of the horizontal bars 141 and the vertical bars 142 may be connected at one end to the corresponding intersection of the horizontal bar 141 and the vertical bar 142, or connected at both ends to such intersections. With this configuration, it is still possible to suppress degradation in performance of the indoor unit 1 as compared to Embodiment 1.

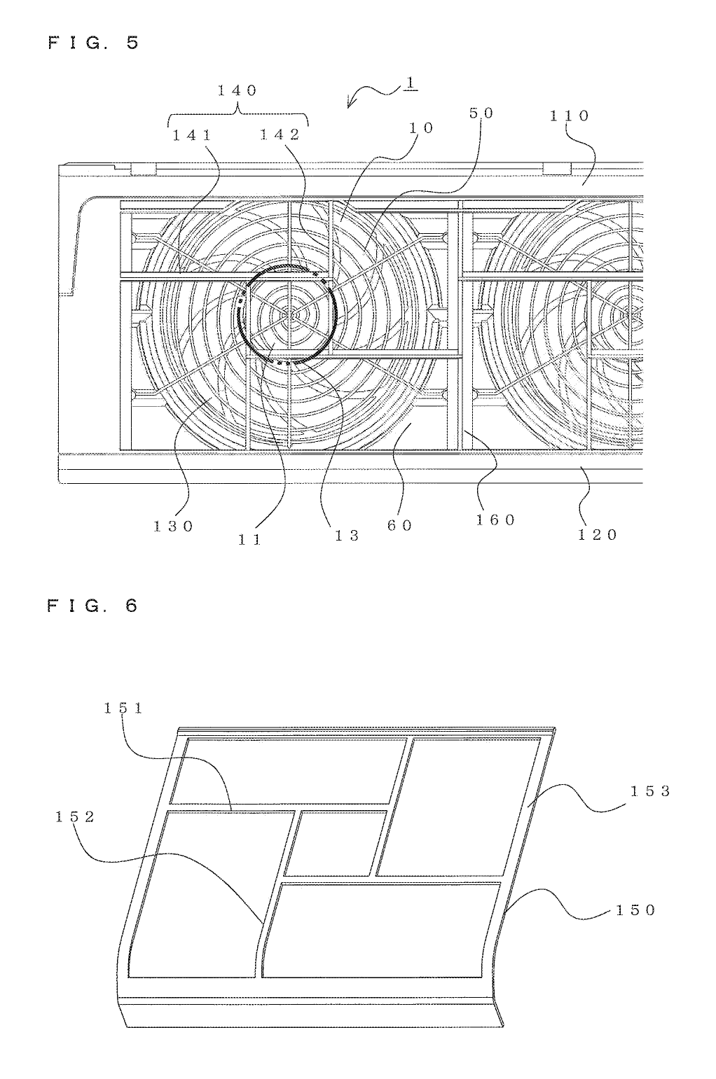

When the filter 150 is to be included in the indoor unit 1 illustrated in FIG. 5, the filter 150 configured, for example, as illustrated in FIG. 6 may be placed such that when the filter 150 is mounted on the casing 100, the horizontal bars 151 and the vertical bars 152 face the horizontal bars 141 and the vertical bars 142, respectively, in the air inlet 130. With this filter 150 included in the indoor unit 1, it is still possible to suppress degradation in performance of the indoor unit 1, such as an increase in noise level and a deterioration of input to the fan motor 20.

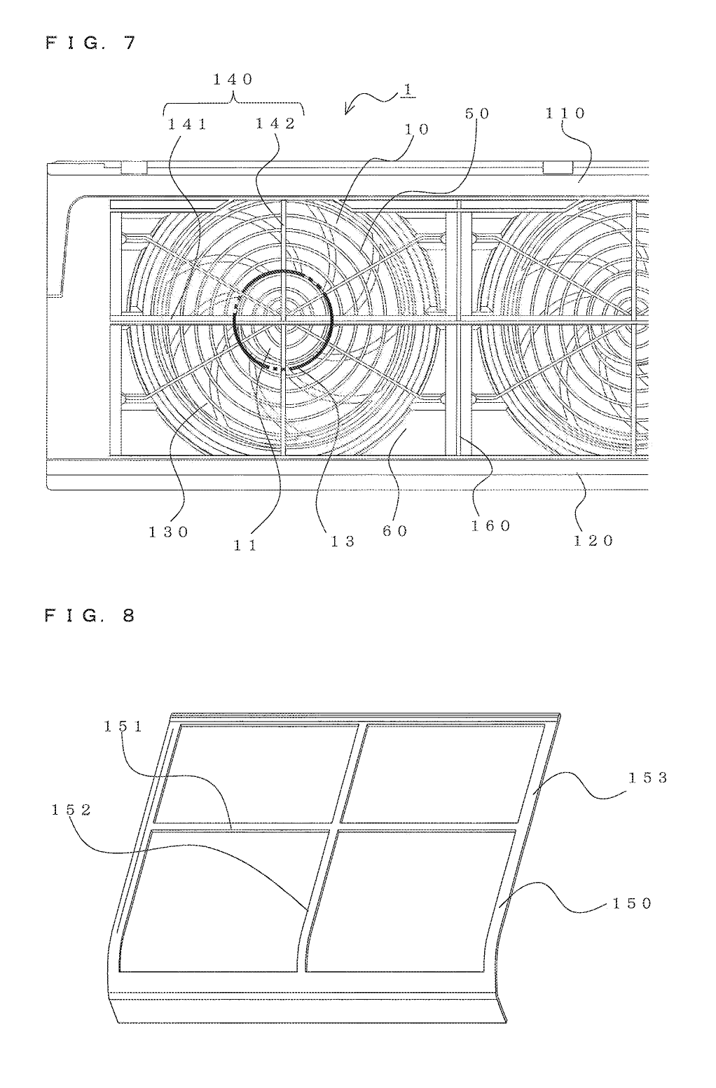

For example, if the strength of the casing 100 (i.e., indoor unit 1) can be ensured by one horizontal bar 141 and one vertical bar 142, the bars 140 may be configured as illustrated in FIG. 7.

FIG. 7 is a plan view illustrating the vicinity of the air inlet in another example of the indoor unit of the air-conditioning apparatus according to Embodiment 2 of the present invention.

In the indoor unit 1 illustrated in FIG. 7, as in the indoor unit 1 according to Embodiment 1, the horizontal bar 141 and the vertical bar 142 in the air inlet 130 are located within the virtual cylinder 13 in a cross-section perpendicular to the longitudinal direction of these bars. However, in the indoor unit 1 illustrated in FIG. 7, unlike in the indoor unit 1 according to Embodiment 1, the bars 140 include one horizontal bar 141 and one vertical bar 142.

With this configuration of the bars 140, as compared to the indoor unit 1 of Embodiment 1 and the indoor unit 1 illustrated in FIG. 5, it is possible to reduce the area of the horizontal bar 141 and the vertical bar 142 that overlap with the blades 12 of the propeller fan 10 when the horizontal bar 141 and the vertical bar 142 are projected onto the propeller fan 10 along the rotation axis of the propeller fan 10. Therefore, as compared to the indoor unit 1 of Embodiment 1 and the indoor unit 1 illustrated in FIG. 5, it is possible to reduce turbulent wake flow of the horizontal bar 141 and the vertical bar 142 into the blades 12 which are turning at high speed, and suppress degradation in performance of the indoor unit 1, such as an increase in noise level and a deterioration of input to the fan motor 20.

In the indoor unit 1 illustrated in FIG. 7, the horizontal bar 141 and the vertical bar 142 are connected at both ends to the edge of the air inlet 130. Alternatively, at least one of the horizontal bar 141 and the vertical bar 142 may be connected at one end to an intersection of the horizontal bar 141 and the vertical bar 142. With this configuration, it is possible to further suppress degradation in performance of the indoor unit 1.

When the filter 150 is to be included in the indoor unit 1 illustrated in FIG. 7, the filter 150 configured, for example, as illustrated in FIG. 8 may be placed such that when the filter 150 is mounted on the casing 100, the horizontal bar 151 and the vertical bar 152 face the horizontal bar 141 and the vertical bar 142, respectively, in the air inlet 130. With this filter 150 included in the indoor unit 1, it is still possible to suppress degradation in performance of the indoor unit 1, such as an increase in noise level and a deterioration of input to the fan motor 20.

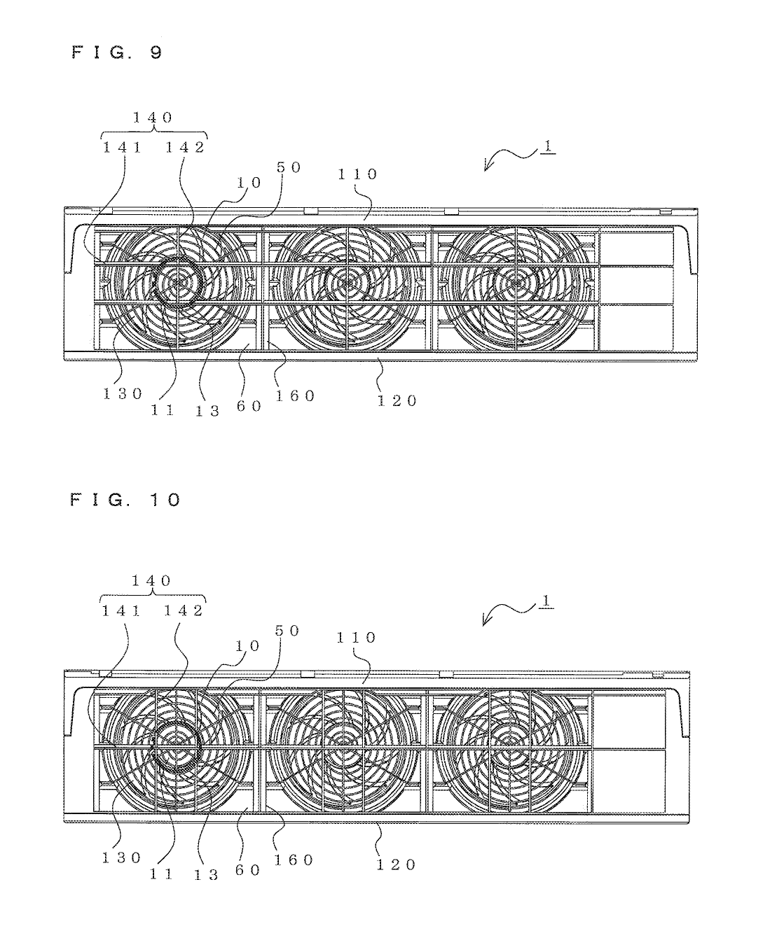

In the indoor units 1 of Embodiment 1, FIG. 5, and FIG. 7, the bars 140 in the air inlet 130 include the horizontal bars 141 and the vertical bars 142 in equal numbers. However, the configuration of the bars 140 is not limited to this. The present invention can be carried out even when the number of the horizontal bars 141 differs from that of the vertical bars 142. For example, as illustrated in FIG. 9, the bars 140 may include two horizontal bars 141 and one vertical bar 142. For example, as illustrated in FIG. 10, the bars 140 may include one horizontal bar 141 and two vertical bars 142. For example, the bars 140 may include the horizontal bars 141 alone or the vertical bars 142 alone. The maximum number of the horizontal bars 141 and the vertical bars 142 is not limited to two. For example, the bars 140 may include three or more horizontal bars 141 and three or more vertical bars 142. In other words, the present invention can be carried out as long as bars in the air inlet 130 are located within the virtual cylinder 13 in a cross-section perpendicular to the longitudinal direction of the bars.

### REFERENCE SIGNS LIST

1: indoor unit

10: propeller fan

11: boss

12: blade

13: virtual cylinder

20: fan motor

30: propeller-fan mount unit

31: bell mouth

32: fan-motor securing part

40: propeller fan assembly

50: fan guard

60: securing component

70: heat exchanger

80: wind-direction flap

90: drain pan assembly

91: front drain pan

92: rear drain pan

100: casing

101: air outlet

110: housing

120: panel

130: air inlet

140: bar

141: horizontal bar

142: vertical bar

150: filter

151: horizontal bar

152: vertical bar

160: guide

1. An indoor unit of an air-conditioning apparatus, comprising:
a casing having an air inlet at the top thereof and an air outlet on a lower side of the front thereof;
at least one propeller fan disposed in the casing and located downstream of the air inlet, the propeller fan being provided with a fan guard; and
a heat exchanger disposed in the casing and located downstream of the propeller fan, the heat exchanger being configured to exchange heat between air sucked into the casing by the propeller fan and refrigerant,
wherein a plurality of bars are provided in the air inlet; and
the bars in the air inlet are located, in a vertical cross-section perpendicular to the longitudinal direction of the bars, within a virtual cylinder obtained by projecting a boss of the propeller fan in the direction of the rotation axis of the propeller fan.

2. The indoor unit of the air-conditioning apparatus of claim 1, wherein the bars in a region corresponding to the propeller fan include at least one vertical bar and at least one horizontal bar.

3. The indoor unit of the air-conditioning apparatus of claim 2, wherein at least one end of at least one of the vertical bar and the horizontal bar is connected to an intersection of the vertical bar and the horizontal bar.

4. The indoor unit of the air-conditioning apparatus of claim 1, wherein the bars in a region corresponding to the propeller fan include at least one vertical bar.

5. The indoor unit of the air-conditioning apparatus of claim 1, wherein the bars in a region corresponding to the propeller fan include at least one horizontal bar.

6. The indoor unit of the air-conditioning apparatus of claim 1, further comprising a filter having an outer frame and a plurality of bars formed within the outer frame, the filter being mounted between the air inlet and the propeller fan,
wherein the bars of the filter are configured to face the respective bars in the air inlet when the filter is mounted.
